(19) United States
(12) Patent Application Publication
(10) Pub. No.: US 2016/0359451 A1
(43) Pub. Date: Dec. 8, 2016

(54) APPARATUS AND METHOD FOR SOLAR PANEL ON-BOARD WIRING

(71) Applicant: LUMETA, LLC, Irvine, CA (US)

(72) Inventors: ERWANG MAO, Palo Alto, CA (US); BRIAN JOSEPH FLAHERTY, Alamo, CA (US); TIMOTHY MICHAEL DAVEY, Newport Beach, CA (US)

(21) Appl. No.: 14/732,010

(22) Filed: Jun. 5, 2015

(51) Int. Cl. H02S 40/36; H01L 31/048

(52) U.S. Cl. CPC H02S 40/36; H01L 31/048

(57) ABSTRACT

A photovoltaic module generates electrical power when installed on a roof. The module is constructed as a laminated sandwich having a transparent protective upper layer adhered to a photovoltaic layer. The photovoltaic layer is adhered to the top of a rigid layer, preferably formed from a fiber reinforced plastic. A tapered edge seal is disposed about the peripheral outer edge of the module, so that water and debris easily run off. Preferably, the tapered edge seal is disposed adjacent the photovoltaic layer, and above the rigid substrate layer. The tapered edge seal is thinner at the outer peripheral portion thereof than at a portion thereof adjacent the photovoltaic layer. The laminated module preferably has a layer of double stick tape on the bottom to adhere the module to the surface of a roof.

### BACKGROUND OF THE INVENTION

### 1. Field of the Invention

The present invention relates to solar panels/modules for generating electrical energy, and more particularly to photovoltaic panels/modules with on-board wiring management structures.

### 2. Description of the Related Art

Conventional photovoltaic modules for generating electrical power for residences and businesses are often flat and are placed on a portion of a roof that is exposed to the sun. Historically, such modules were placed on structures erected on the roof to support and protect the modules. More recently, photovoltaic modules have become available that can be mounted directly on a flat or tilted roof. See, for example, US Patent Application Publication No. 2005/0178428 A1 to Laaly et al., (the entire contents of which are incorporated herein by reference), which discloses a module that incorporates a roofing membrane into the module structure. The module is intended to be installed on a new roof or replacement roof with the membrane providing moisture protection for the underlying structure as well as providing electrical power.

See also U.S. Pat. Nos. 7,531,740 and 7,557,291 both to Flaherty, et al., the entire contents of both of which are incorporated herein by reference. These patents disclose such photovoltaic modules for roof-top installation.

A problem with above mentioned direct roof top attached crystalline silicon photovoltaic cell based solar modules is their installation tends to take a great deal of time in laying the panels out and then electrically connecting plural panels together to form the desired array. An electrician is usually needed, and loose wiring often is left exposed to the elements. Some solutions have been proposed in which plug-and-play type side connectors have been proposed to quickly plug together plural solar modules. See, for example, U.S. Pat. Nos. 7,713,089; 7,819,114; 8,455,752; and 8,922,972; and also USPPNs 2008/0149170; 2013/0263910; and 2014/0090694; the contents of each of which are incorporated herein by reference. However, these proposed solutions still require a skilled worker to run the different required wirings from module to module, or from groups of modules to groups of modules. Thus, what is needed is a solar panel/module system that is quick and easy to install, and provided superior electrical connections.

### SUMMARY OF THE INVENTION

The photovoltaic module described herein and illustrated in the attached drawings enables electricity-generating solar modules to be installed quickly and with reliable electrical connections.

In accordance with one aspect according to the present invention, a photovoltaic module has an upper transparent protective layer, and a photovoltaic layer positioned beneath the upper transparent protective layer. The photovoltaic layer has a plurality of electrically interconnected photovoltaic cells disposed in an array. A rigid substrate layer is positioned beneath the photovoltaic layer. A first plurality of wire support clips is disposed along a first edge of the photovoltaic module and disposed so as not to protrude beyond an outer edge of said first edge. A second plurality of wire support clips is preferably disposed along the first edge of the photovoltaic module and disposed so as to protrude beyond said outer edge of the first edge.

In accordance with another aspect according to the present invention, a photovoltaic module has a substantially rectangular panel having a top surface with a plurality of photovoltaic cells disposed thereon in an array. An electrical device is preferably disposed on the top surface substantially adjacent a first edge of the rectangular panel. A first plurality of wire support members is disposed along the first edge of the rectangular panel, and is disposed so as not to protrude beyond an outer edge of the first edge. Preferably, a second plurality of wire support members is disposed along a second edge of the rectangular panel, and is disposed so as not to protrude beyond an outer edge of the second edge, the second edge being substantially perpendicular to the first edge.

In accordance with a further aspect according to the present invention, a photovoltaic module has a rectilinear panel having a top surface with a plurality of photovoltaic cells disposed thereon in an array. All four edges of the panel are preferably tapered edges. At least one panel edge has a first plurality of wire support members attached thereto, each of the wire support members having a bias device for releasably holding an electrical wire. An electrical device is preferably disposed on the top surface, substantially adjacent the at least one panel edge.

In accordance with yet another aspect according to the present invention, a method of making a photovoltaic module includes (i) providing a rectilinear photovoltaic panel having a plurality of cells disposed on a top surface thereof, and (ii) attaching a plurality of wiring support members along at least one edge of the panel so that no wiring support member protrudes beyond an outer edge of the at least one edge of the panel.

### BRIEF DESCRIPTION OF THE DRAWINGS

Certain aspects in accordance with embodiments of the present invention are described below in connection with the accompanying drawing figures in which:

FIGS. 1a and 1b illustrate a perspective view of a first embodiment of a laminated photovoltaic module and rear view of the module, respectively, according to an embodiment of the present invention.

FIG. 2 illustrates a top view of the photovoltaic module of FIG. 1a with junction box showing conductors;

FIG. 3 illustrates a perspective view of the photovoltaic module of FIG. 1a, showing the wiring support structure according to a preferred embodiment;

FIG. 4 illustrates another perspective view of the photovoltaic module of FIG. 3;

FIG. 5 illustrates a top plan view of the FIG. 4 embodiment;

FIG. 6 illustrates another top plan view of the FIG. 4 embodiment;

FIGS. 7a, 7b, 7c, and 7d illustrate close-up perspective views of wiring support clips usable in the photovoltaic module of FIG. 1a;

FIGS. 8a and 8b illustrate close-up perspective view of wiring support clips usable in the photovoltaic module of FIG. 1a; and

FIGS. 9a and 9b illustrate perspective and cross-sectional views of an embodiment including wiring trays.

### DETAILED DESCRIPTION OF THE PREFERRED EMBODIMENTS

Briefly, the present on-board wire/cable management structures for both residential and commercial photovoltaic (“PV”) modules are designed to: (i) keep module interconnection wiring, jumpers, and homerun cables off roof surfaces, (ii) minimize system install time and wire tray usage, (iii) minimize installation errors in the field, and (iv) enhance protection from weather and solar related degradation. The low profile (height) of the wire clips does not substantially increase wind resistance of the installed photovoltaic systems and also enhances the aesthetics thereof. As wire management clips are exposed to direct sun light, stainless steel clips are preferred to minimize the impact of UV degradation. UV-resistant polymer materials can also be used for the wire clips.

PV wiring requirements for residential roof top installations should meet the National Electrical Code (“NEC”) latest revision, currently 2014. Many Authorities Having Jurisdiction (“AHJs”), such as state, county, and municipal governing bodies follow the NEC code. But, some local codes could be more stringent. For possible PV commercial and industrial uses, PV module interconnection requirements are typically defined by the AHJ for: AC modules; DC modules with module level power control; DC modules with string power control, i.e. with line inverters; Homerun cable requirements, etc.

Preferably, the PV installation should involve no cable (or any other) penetration through roof deck. Cables should run on the roof only. With the present invention, those cables will be kept up off of the roof and substantially co-planar with the PV panels. Preferably, Underground Service Entrance (“USE”)-2-rated or Underwriters Labotratory (“UL”) 4703-rated or equivalent AC/DC cables are used, for direct, exposed to sun irradiation applications. Cables and connectors should not be in direct contact with the roof. This is achieved in the present invetion where the co-planar wiring support clips hold the cables above the roof surface. Cable connectors are preferably interlocked, and the connector interlocking preferably is by hand-only. Disconnecting is preferably achieved with tools per NEC 208 and 211. Interconnection cables are preferably fixed within 300mm from a junction box, as is provided with the clips according to the present invention. Cables should be fixed in place every 1.4 m of run-length; again, easily achieved with the clips according to the present invention, which fix the cables at approximately every 6-46 inches, preferrably about 12 inches.

The cabling/wiring that runs from the coupled-together plural PV panels to an electrical/mechanical collection device is termed the homerun cabling. Homerun cable should preferably be kept off roof, which is accomplished according to the present invention, and may be routed through one or more electrical conduits. The clips according to the present invention are preferably sized to accommodate one or a plurality of homerun cables. Usable conduit types include Rigid Metal Conduit (“RMC”) and/or Intermediate Metal Conduit (“IMC”). UV resistant, liquid-proof liquid tight flexible plastic conduit may also be used. Cables in conduits should be water resistant. Conduit dimensions may be determined by fill-factor and cable cross section areas. Steel junction boxes with knock-outs can be used for interconnecting cables and/or wires to homerun cables.

As will be described in greater detail below, preferably, one or two wire clips may be located adjacent to the junction box, and/or the DC power optimizer, and/or the micro inverter, and/or packet energy transfer (PET) module, mounted on the PV module. Additional clips may be added to a module for jumpers and homerun cable management. The locations of the additional clips may be on the same side of the junction box and/or adjacent to the junction box side and/or opposite to the junction box side, depending on any specific application. A number of, 0 to (but not limited to) 20, additional clips can be added to a module based on any specific application. The original and/or additional clips may be added at the factory, on the work-site, or even on the roof.

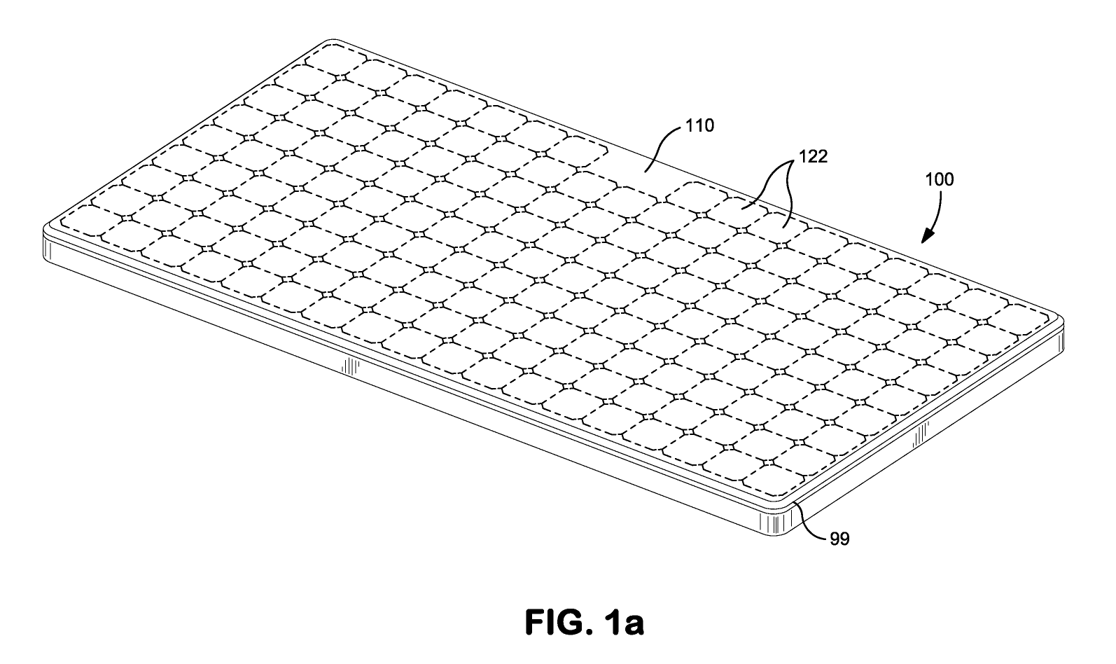

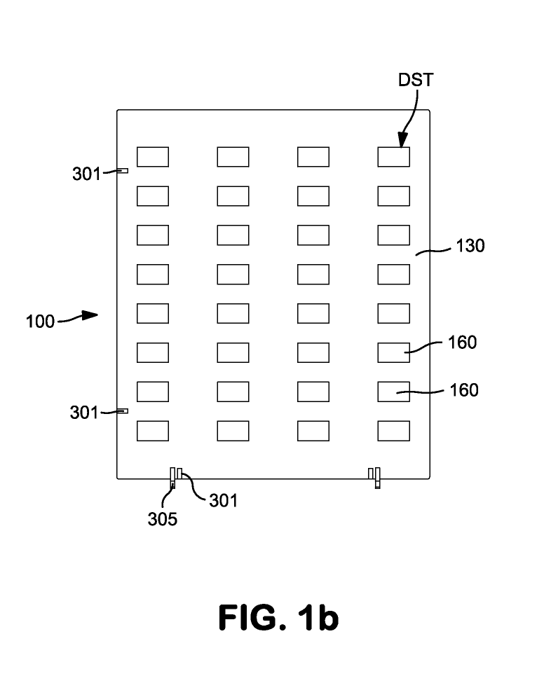

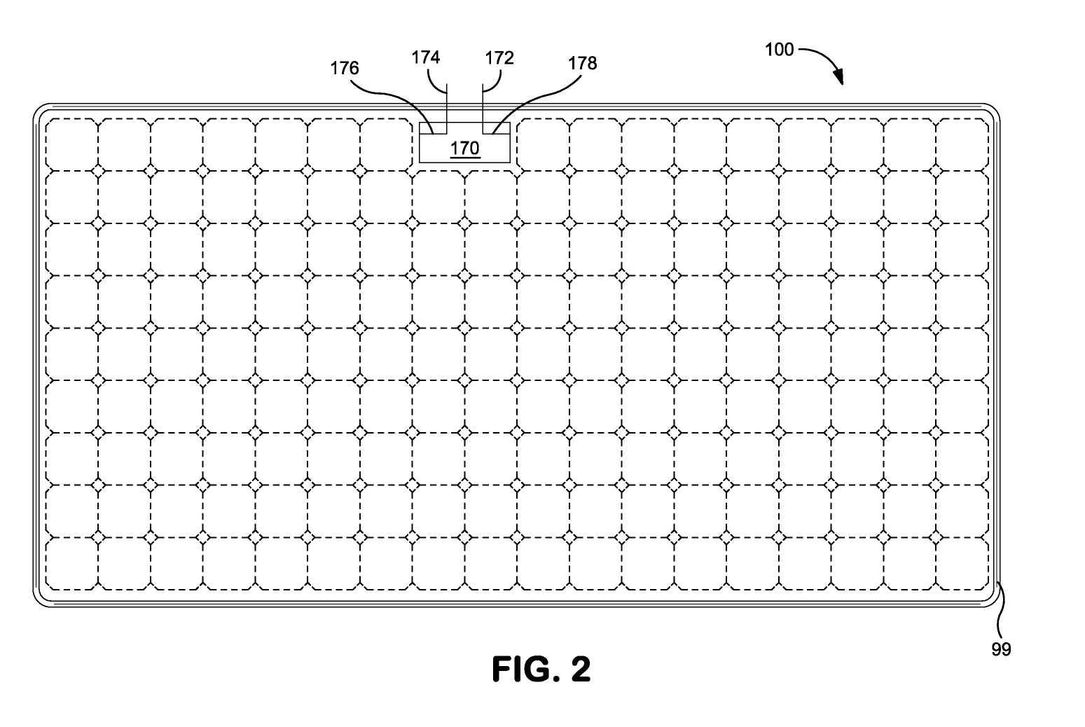

As illustrated in FIGS. 1a, 2, 3, 4, and 5, of co-pending U.S. application Ser. No. 14/454,226, filed Aug. 7, 2014 (the contents of which are incorporated herein by reference), and with reference to FIGs. 1a and 2 of the subject application, a laminated photovoltaic module 100 is preferably configured as a generally rectangular module, which is sized and shaped in accordance with the sizes and shapes of conventional building materials, such as a 4×8 foot module. Thus, the module 100 can be handled by a construction crew without requiring any special material handling equipment. Of course, the module 100 may be any convenient size (4×8, 4×4, 3×3, 3×2, 2×2, 2×1, 1×1, etc.), and shape (square, round, triangular, trapezoidal, etc.) useful in the construction industry, and with either rounded corners or substantially right angle corners. The module 100 is preferably assembled in a factory or other suitable environment so that the module 100 is complete and ready to install on a substantially flat roof (which may be horizontal or tilted), or sloped shingle roofs, such as, but not limited to, asphalt, laminated, wood, slate, concrete, or other location having adequate exposure to the sun. In one preferred embodiment, as shown in FIGS. 1a and 2, 3, the module 100 has dimensions of approximately 101 centimeters (˜40 inches) by 196 centimeters (˜77 inches) and has a thickness of approximately 0.5 centimeter (0.2 inch). In another preferred embodiment, the module 100 has dimensions of approximately 101 centimeters (˜40 inches) by 101 centimeters (˜40 inches) and has a thickness of approximately 0.3 centimeter (⅛ inch) when installed. In fact, the thickness of the module is preferably the same as (or thinner than) the thickness of the laminated roofing shingle. Thus, the module 100 does not add significant height to a roof structure and will not block water flow on sloped roofs. In yet another embodiment, the module 100 has dimensions of approximately 101 centimeters (˜40 inches) by 239 centimeters (˜94 inches) and has a thickness of approximately 0.5 centimeter (0.2 inch). In a particularly preferred embodiment, the module has dimensions of 101 cm×120 cm×0.3 cm.

As shown in FIG. 1a, the module 100 preferably has a transparent upper protective layer 110 that faces upward and is exposed to the sun. A middle layer is preferably positioned beneath the upper protective layer 110. The middle layer comprises a plurality of photovoltaic cells 122 electrically interconnected to form a photovoltaic array. The middle layer preferably rests on a rigid lower substrate. The middle layer is preferably secured to the rigid lower layer by a lower adhesive layer. The middle layer is preferably secured to the upper protective layer 110 by an upper adhesive layer. The middle layer is thus encapsulated between the lower adhesive layer and the upper adhesive layer.

The upper protective layer 110 preferably provides impact protection as well as weather protection to the module 100. The upper protective layer 110 advantageously comprises of a transparent flexible polymer material, such as, but not limited to Ethylene tetrafluoroethylene (ETFE), a fluorine based co-polymer, which is formed into a film layer of suitable thickness (e.g., approximately 0.005-0.013 centimeter (0.002-0.005 inch)). Thus, the photovoltaic cells 122 in the middle layer are exposed to direct sunlight without being exposed to moisture and other climatic conditions and without being exposed to direct impact by feet, falling objects, and debris. Tempered glass having a suitable thickness may also be used as the upper protective layer 110.

The rigid lower layer substrate preferably comprises fiber reinforced plastic (FRP). For example, the FRP layer advantageously comprises a polyester resin with embedded stranded glass fibers. Preferably the said FRP layer has a thickness of approximately 0.1 centimeter to 1 centimeter (0.079 inch-0.39 inch), and additionally, the said FRP lower surface can be either flat or with a defined pattern/rib. The lower layer of FRP thus provides an advantageous combination of rigidity, light weight, very low permeability, and flatness.

As shown in FIG. 2, the preferred embodiment provides that the photovoltaic cells 122 are electrically interconnected in a series-parallel configuration in a conventional manner to provide a suitable output voltage or a desired photovoltaic module form factor. For example, FIGS. 1a and 2 show a photovoltaic module suitable for flat roof application. Photovoltaic cells 122 are arranged in 6 rows of 12 cells each; however, one, two, or more cells are preferably omitted from at least one of the edge rows to provide room for positioning an electrical enclosure, such as, but not limited to junction box 170 (having a first weather-resistant electrical conductor 172 and a second weather-resistant electrical conductor 174), module power optimizer, micro inverter, and other useful electrical control and/or power-conditioning circuitry, as discussed above. The photovoltaic module 100 preferably includes two module output conductors 176, 178 (e.g., FIG. 2) that extend from the top surface of the middle layer in the area of the omitted photovoltaic cell(s). Each of the module output conductors 176, 178 is preferably connected to a respective one of the weather-resistant electrical conductors 172, 174 within the electrical enclosure 170 after the photovoltaic module 100 is laminated, as discussed below. In an alternative embodiment, the junction box may be mounted on the bottom surface of the solar panel, opposite the side on which the solar cells are mounted.

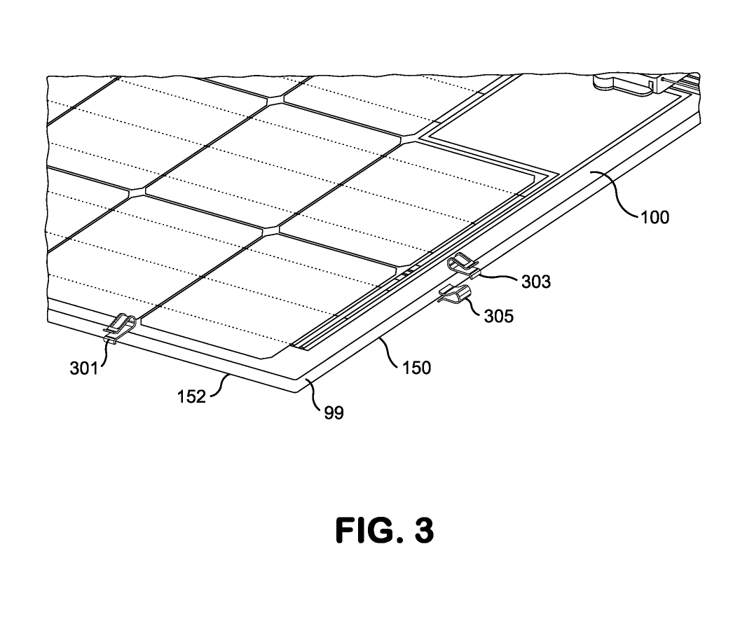

FIG. 3 is a close-up perspective view of the FIG. 1a embodiment, showing plural wiring support members 301, 303, and 305. In this embodiment, the wiring support members 301, 303, and 305 are stainless steel clips which are (preferably) permanently attached to the edges of the PV module via screw(s), rivet(s), glue(s), interference fit, hot-melt, tape(s) etc., or any combination of these. Preferably, the clips are installed on the sloped surfaces of the tapered edge 99. The clips may be installed in the factory either during or after manufacture of the PV module 100. Alternatively, the clips may be installed in the field, for example, with weather-proof adhesive tapes, foam tapes, two-sided tapes, hot melt, glue-gun, butyl tape, etc. The clips are sized and dimensioned so as to support one or more of (i) wire(s) and/or cable(s), (ii) conduit(s) which hold one or more wire(s) and/or (cables), and/or (iii) wiring tray(s) which hold one or more of (i) and/or (ii). As one example, plural clips 305 may hold a wire, or a homerun cable, or be configured to releasably (or permanently) couple with a corresponding receptacle(s) (or protrusion) in the side of a wire tray. Most preferably, each clip 305 is multi-modal, and can support one or more wires, and/or one or more cables, and/or one or more conduits, and be coupleable to corresponding structure on/in a wiring tray.

The clips 301, 303, and 305 are preferably disposed on at least two perpendicular edges of the PV module 100. In the most preferred embodiment, the clips are disposed along a front edge 150, a first side edge 152, and a second side edge (not shown). Of course, clips can be provided on all four edges. As can be seen in the drawings, the clips 301 and 303 are disposed so that the clip structure does not protrude substantially beyond the outer edge of the edges 150 and 152. As used herein, “does not protrude” encompasses insubstantial protrusions where the clip is affixed to the edges 150 and 152, as shown in the Figures. Thus, each of clips 301 and 303 has an opening which faces outward away from an interior of the PV module 100. These clips are useful for wiring one module to another, and their design keeps the wires/cables from overlying the photovoltaic cells. Clip 305, on the other hand, protrudes beyond an outer edge of the edge 150, and has an opening which faces inward toward an interior of the PV module 100. Clips 305 are useful for homerun wires/cables which carry the electricity to a roof junction box (not shown) where the power is collected and directed to a standard electrical panel.

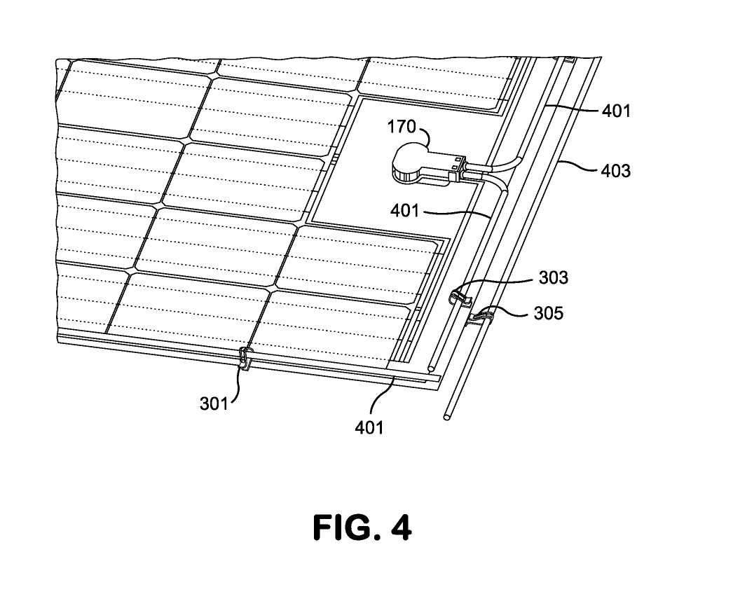

FIG. 4 shows the PV module 100 with wires/cables/conduits 401 which are held by clips 301 and 303; and wires/cables/conduits 40 which are held by one or more of clip 305, The wires 403 may comprise homerun cabling. Also shown in FIG. 4 is one or more electrical devices 170, which may comprise electrical circuitry (discussed above), which collects power from the solar cell (may condition it), and directs it off-board via wires 401. The device 170 may conveniently be disposed on an upper surface of the PV module 100 where one or more (preferably two) cells are missing from the array. Note that the clips are preferably designed so that the wires/cables may be easily inserted therein and/or removed therefrom. Note also that the device 170 is disposed between two rows of solar cells (running substantially horizontally in the Figure), but substantially in-line with the row of solar cells (running substantially vertically in the Figure).

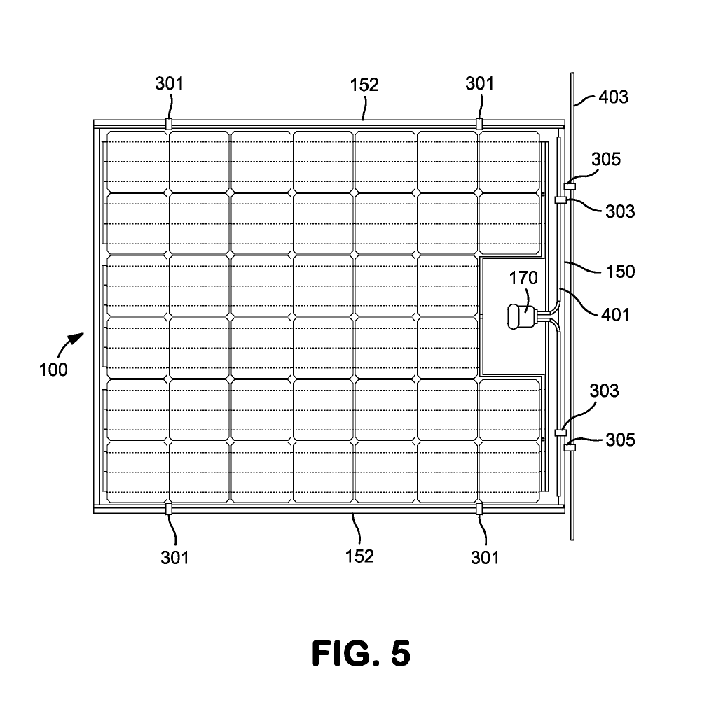

FIG. 5 is a top plan view of the FIG. 4 embodiment showing a substantially square PV module 100, with clips 301 on left and right side edges 152 of the module, and clips 303 and clips 305 on the front edge 150 thereof. Preferably, the edges 152 are perpendicular to the edge 150.

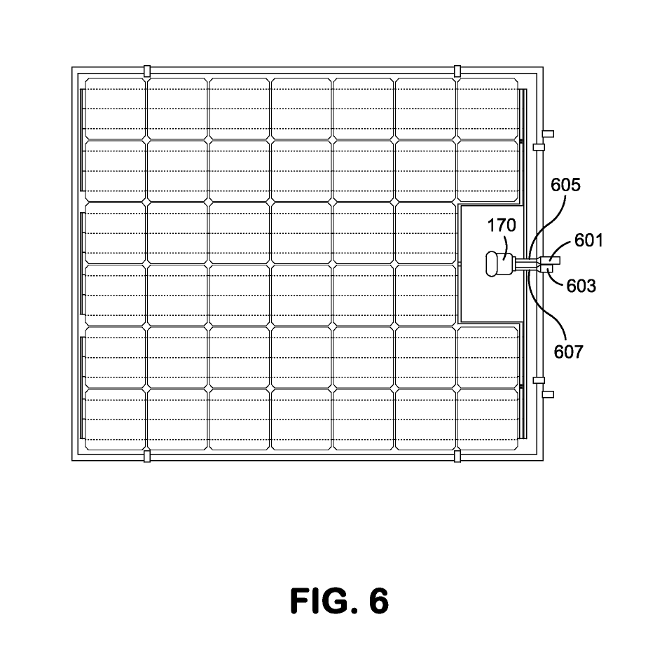

FIG. 6 is a top plan view of the FIG. 4 embodiment showing a preferred configuration in which the electrical device 170 is equipped with weather resistant plugs 601 and 603, each coupled to the device 170 with respective short, flexible, weather resistant cables 605 and 607. The plugs 601 and 603 can be removably (or permanently) coupled to corresponding plugs on wires/cables 401 and/or 403.

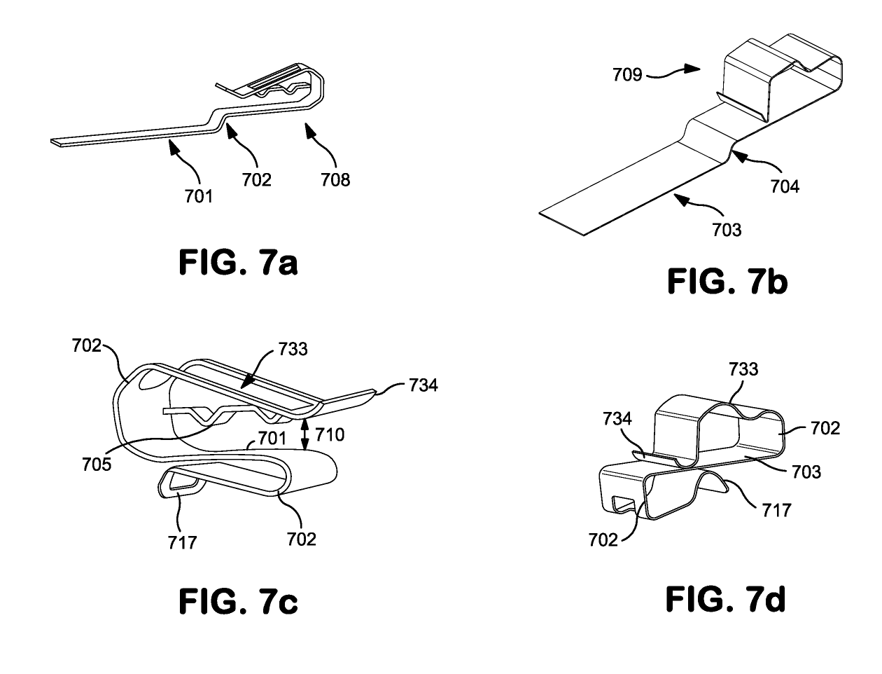

FIGS. 7a, 7b, 7c, and 7d are perspective views of various clips which may be used in accordance with the present invention for holding wires/cables, etc., as discussed above. The clips may be modified Heyco SunRunner clips (FIG. 7a), and SunRunner 2 clips (FIG. 7b), with dimensions based on cable diameters. These clips may be provided by Heyco Products, Inc., 1800 Industrial Way, Toms River, N.J. 08755. Flat extensions, 701 and 703 may replace the SunRunner (FIG. 7c) and SunRunner 2 (FIG. 7d) clips' crimp structures, respectively. Each flat extension is preferably 1-1.5 inch long and with the same width and thickness to the SunRunner and SunRunner 2 clips. In one preferred embodiment, the flat portion is extended from the wire/cable clip portion. More preferably, a gradual bend 702 and 704, of 3-6 mm in height is inserted between the flat portion and the wire/cable clip portion, that substantially levels (makes horizontal) the wire/cable clip portion, 708 and 709, respectively to the top surface of the PV module.

The clips 301 and/or 305 preferably include an upper portion 733 which is biased in a direction substantially orthogonal to the plane of the upper surface of the PV module 100. This biasing acts to keep the wiring/cabling/conduits securely held within the clip. The upper portion 733 preferably includes an upwardly extending tang 734, which acts to guide wiring/cabling/conduits into the interior of the clip during installation. Note that the clip has an opening 710 which is preferably narrower than an interior thereof. In a preferred embodiment, the clip also includes an interior bias member 705, which acts to compress wiring/cabling/conduits downward to the upper surface of the base portion 701. This will keep the wiring/cabling/conduits securely within the clip even in difficult weather and/or installation conditions. In a further preferred embodiment, some or all of the edges of the clip are rounded or beveled to prevent damage the sheathing of the wiring/cabling/conduits.

The clips 301 and 305 may be identical (size and/or shape), or different, depending on the projected installation. For example, the clips 305 may be larger than the clips 301, when they are used for bigger cabling, such as truck cable for AC micro-inverters. The clips may be sized differently, but have identical shapes, or have differing shapes but sized identically, again depending on installation. Preferably, at least one clip has a base portion 701 used to affix (permanently or removably) the clip to the lower surface of the PV module 100. As discussed above, the clip may be affixed by bonding, epoxy, tape, glue, screws, rivets, or any convenient method. The s-bend 702 is used to level wire/cable clip portion 708 to the module 100 upper surface 110, and keeps wires/cables off the roof surface. The flat base 701 is sufficiently attached to the PV module lower surface 105. The downwardly projecting tang 717 may be used for ease of installation of the clip onto the PV module. The base 701 may include a bias which acts to keep the clip pressed to the PV module edge.

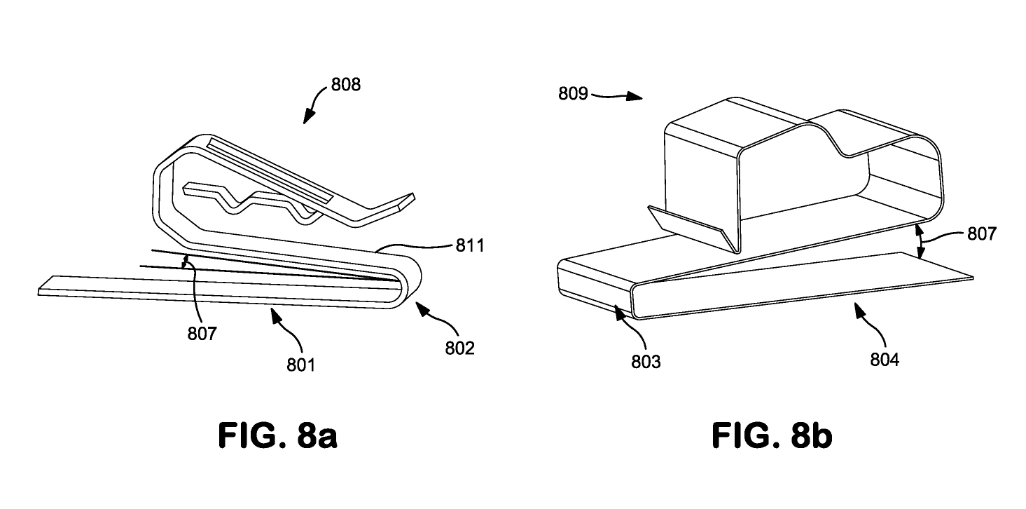

FIGS. 8a and 8b show other preferred embodiments that can be used in the present invention. The clips are modified Heyco SunRunner and SunRunner 2 clips, as discussed above. The flat portions 801 and 804 are bent approximately ˜180 degrees, to extend under the wire/cable clip portions, 808 and 809, respectively. More preferably, a bending radius of 1.2 mm to 2.5 mm, 802 and 803, is used to clear the wire/cable clip portion on the module 100 upper surface. Even more preferably, a bending angle of about 5 degrees to about 10 degrees, 807, is used for a flat portion 811 that raises the wire/cable clip portion on the top of the module 100 upper surface, and prevents wires/cables from touching the module upper surface.

The preferred method of installation of the module 100 on a composite shingle roof comprises applying a layer of Peel-And-Stick (PAS) tape to the bottom surface of the rigid lower layer 130. Positions of the PAS tapes are designed for common roof shingle course width, nominally about 5½ inches apart (FIG. 1b). Preferably, the tape layer 160 comprises a suitable double-stick tape, such as, for example but not limited to, a self-sealing tape having a formulation of resins, thermoplastics, curing rubbers, and non-curing rubbers. The double-stick tape has adhesive on both sides. When manufactured, the double-stick tape has a release layer on each side to prevent adhesion. One release layer is advantageously removed during the process of manufacturing the modules. The exposed adhesion side of the tape layer 160 is positioned on and adhered to the bottom surface of the rigid lower layer 130 before shipping the module 100. Then, during installation of the module 100, the remaining release layer is removed so that the module can be adhered to the surface of an existing roof. The surface of the existing roof is cleaned and suitably prepared to receive the module 100. After installation, suitable pressure is applied to the upper layer 110 of the module 100 to permanently adhere the module to the surface of the roof. In one preferred embodiment, The PAS tape 160 comprises plural Butyl tape in an array of, for example, 8 rows by 4 columns of tape-squares. Tape size can be, but not limited to: 2×4 inches to 4×4 inches. Preferably, the lower edge of the butyl tape is aligned approximately with the lower edge of each shingle course for installation, but the upper edge of the butyl tape may be spaced somewhat from the top edge of the module 100.

Once the PV module is installed on the roof, the wiring/cabling/conduits/trays are installed by simply pressing them into/onto the clips. The wiring/cabling/conduits/trays are then connected, pulled tight, and run to the appropriate junction box.

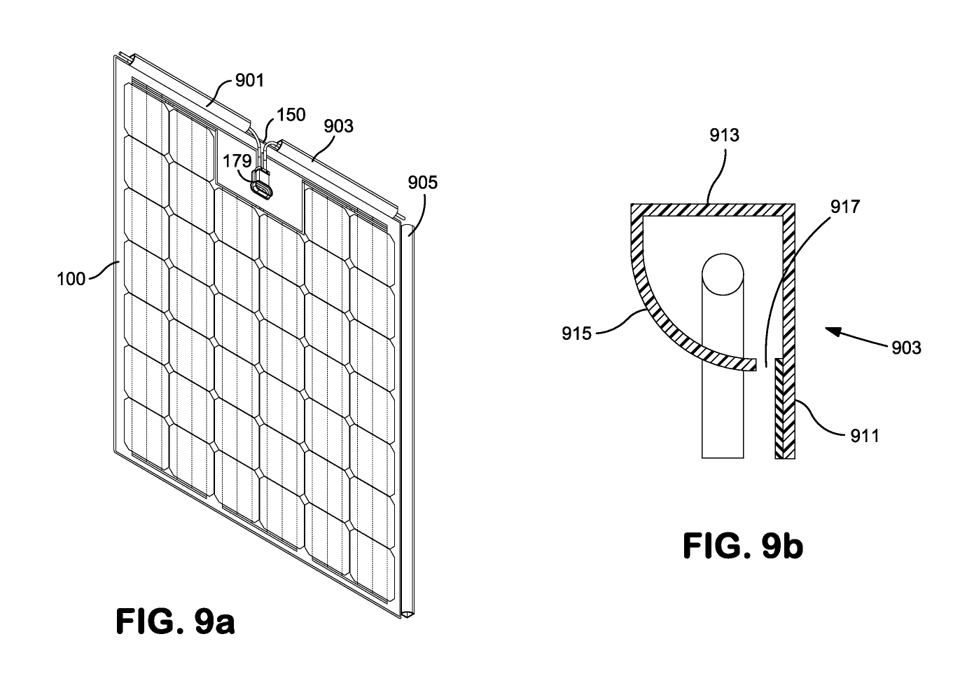

FIGS. 9a and 9b are perspective and partial cross-section views of an embodiment using cable trays instead of (or in addition to) the wiring clips. This embodiment provides improved weather protection for the wiring/cables/conduits, prevents workers from tripping over or otherwise disturbing the wires, and provides an enhanced aesthetic appearance. Of course, whole or partial wiring trays may be used in conjunction with clips 301 and/or 305, depending on the desired installation. Preferably, the cable trays 901, 903, and 905 comprise rigid and/or semi-rigid and/or bendable UV and/or weather resistant plastic sheaths having a smooth low profile and a flat bottom cross section, as best seen in FIG. 9b. In one preferred embodiment, cable trays 901 and 903 are affixed to the edge 150 of PV module 100, to accommodate at least the homerun cabling. The tray 905 may be affixed to another side edge of the PV module 100. Of course, cable trays may be provided on one, two, three, or all four edges of the PV module 100. In another preferred embodiment, cable trays can be installed peripheral to the PV module 100 with PAS Butyl tape. The trays are preferably parallel to edges of the PV modules. Each PV module edge may have one, two, three, or more cable trays coupled in series or in parallel. For parallel cable tray installations, each cable tray may be coupleable (releasably or permanently) to one or two adjacent cable trays. The cable trays may be solid, perforated, meshed, or any convenient structure.

In FIG. 9b, the tray 903 preferably comprises a quarter-circle shape having a first, straight side 911, a second straight side 913, and a curved side 915. Preferably, a gap 917 is provided between a distal end of the curved side 915 and a side portion of the first side 911. Note that a distal end of the first side 911 extends beyond the gap 917. This is to make it easy for a workman to lay one or more wires/cables/conduits onto the extended portion of first side 911, and sliding it down through the gap 917, where the above-described geometry keeps the wires/cables/conduits secured in place within the cable tray 903.

Preferably, the cable trays are affixed to the PV module 100 edges with liquid adhesives, tapes, clip, crimp, bolts, screws, rivets, etc. In the most preferred embodiment, the cable trays are affixed to the PV module edge(s) with one or more clips, legs, fixtures, etc. In another preferred embodiment, the cable trays are installed peripheral to the PV module 100 with PAS Butyl tape. The attachment may be permanent or releasable. Preferably, the tray can be affixed to the PV module without tools, either on the roof or adjacent thereto. Of course, the tray may be affixed to the PV modules in the factory. In a preferred embodiment, the clips 301, 303, and 305 may be constructed for use to support the wiring/cables/conduits or to couple to a corresponding receptacle (preferably a biased receptacle) in the cable tray.

The present invention is disclosed herein in terms of a preferred embodiment thereof, which provides an exterior building module as defined in the appended claims. Various changes, modifications, and alterations in the teachings of the present invention may be contemplated by those skilled in the art without departing from the intended spirit and scope of the appended claims. It is intended that the present invention encompass such changes and modifications.

What is claimed is:

1. A photovoltaic module, comprising:
an upper transparent protective layer;
a photovoltaic layer positioned beneath the upper transparent protective layer, the photovoltaic layer comprising a plurality of electrically interconnected photovoltaic cells disposed in an array;
a rigid substrate layer positioned beneath the photovoltaic layer;
a first plurality of wire support clips disposed along a first edge of the photovoltaic module and disposed so as not to protrude beyond an outer edge of said first edge; and
a second plurality of wire support clips disposed along the first edge of the photovoltaic module and disposed so as to protrude beyond said outer edge of the first edge.

2. The photovoltaic module according to claim 1, wherein each wire support clip has at least one bias member configured to move in a direction substantially orthogonal to a plane of the photovoltaic module for insertion of a wire into said each wire support clip.

3. The photovoltaic module according to claim 2, wherein at least one wire support clip has at least one bias member configured to have an opening in a direction outward from an interior of the photovoltaic module.

4. The photovoltaic module according to claim 3, wherein at least one other wire support clip has at least one other bias member configured to have an opening in a direction inward toward an interior of the photovoltaic module.

5. The photovoltaic module according to claim 1, further comprising:
a third plurality of wire support clips disposed along a second edge of the photovoltaic module and disposed so as not to protrude beyond an outer edge of said second edge; and
a fourth plurality of wire support clips disposed along the second edge of the photovoltaic module and disposed so as to protrude beyond said outer edge of the second edge.

6. The photovoltaic module according to claim 5, wherein the second edge is substantially perpendicular to the first edge.

7. The photovoltaic module according to claim 1, further comprising an electrical enclosure box disposed substantially adjacent said first edge and configured to accept wiring carried by at least one of said first plurality of wire support clips.

8. The photovoltaic module according to claim 7, wherein said photovoltaic layer has at least on photovoltaic cell missing from said array, and wherein said electrical enclosure box disposed at a position of the missing photovoltaic cell.

9. The photovoltaic module according to claim 1, wherein said first edge comprises a tapered edge.

10. A photovoltaic module comprising:
a substantially rectangular panel having a top surface with a plurality of photovoltaic cells disposed thereon in an array;
an electrical device disposed on said top surface substantially adjacent a first edge of the rectangular panel;
a first plurality of wire support members disposed along the first edge of the rectangular panel and disposed so as not to protrude beyond an outer edge of said first edge; and
a second plurality of wire support members disposed along a second edge of the rectangular panel and disposed so as not to protrude beyond an outer edge of said second edge, the second edge being substantially perpendicular to the first edge.

11. The photovoltaic module according to claim 10, further comprising a third plurality of wire support members disposed along the first edge of the rectangular panel and disposed so as to protrude beyond said outer edge of the first edge.

12. The photovoltaic module according to claim 11, wherein at least one wire support member of the first, second, and third pluralities of wire support members has an opening facing outward from a corresponding edge of the rectangular panel.

13. The photovoltaic module according to claim 12, wherein at least one other wire support member of the first, second, and third pluralities of wire support members has an opening facing inward from a corresponding edge of the rectangular panel.

14. The photovoltaic module according to claim 10, wherein each of the first and second pluralities of wire support members has bias structure for releasably accepting an electrical wire therein.

15. The photovoltaic module according to claim 10, wherein each of the first and second edges comprises a tapered edge.

16. The photovoltaic module according to claim 10, wherein the electrical device includes at least one connector configured to be detachably coupled to an adjacent photovoltaic module.

17. The photovoltaic module according to claim 16, wherein the at least one connector includes a flexible wire portion disposed between an electrical device body and a plug.

18. A photovoltaic module comprising:
a rectilinear panel having a top surface with a plurality of photovoltaic cells disposed thereon in an array;
all four edges of the panel being tapered;
at least one panel edge having a first plurality of wire support members attached thereto, each of the wire support members having a bias device for releasably holding an electrical wire; and
an electrical device disposed on said top surface substantially adjacent the at least one panel edge.

19. The photovoltaic module according to claim 18, wherein the first plurality of wire support members is disposed so as to not protrude beyond an outer edge of the at least one panel edge.

20. The photovoltaic module according to claim 19, further comprising a second plurality of wire support members attached to said at least one panel edge and disposed so as to protrude beyond the outer edge of the at least one panel edge.

21. The photovoltaic module according to claim 18, further comprising a cable tray coupled to the first plurality of wire support members.

22. A method of manufacturing a photovoltaic module, comprising;
providing a rectilinear photovoltaic panel having a plurality of cells disposed on a top surface thereof; and
attaching a plurality of wiring support members along at least one edge of the panel so that no wiring support member protrudes beyond an outer edge of the at least one edge of the panel.
